(19) United States
(12) Patent Application Publication
(10) Pub. No.: US 2026/0059847 A1
(43) Pub. Date: Feb. 26, 2026

(54) SEMICONDUCTOR CHIP AND METHOD FOR MANUFACTURING SAME

(71) Applicant: Microchip Technology Incorporated, Chandler, AZ (US)

(72) Inventors: Shesh Mani Pandey, Gilbert, AZ (US); Yogesh Kumar Sharma, Colorado Springs, CO (US)

(73) Assignee: Microchip Technology Incorporated, Chandler, AZ (US)

(21) Appl. No.: 19/059,689

(22) Filed: Feb. 21, 2025

Related U.S. Application Data
(60) Provisional application No. 63/684,946, filed on Aug. 20, 2024.

(51) Int. Cl. H10D 84/82; H10D 84/01

(52) U.S. Cl. CPC H10D 84/82; H10D 84/0123

(57) ABSTRACT

A semiconductor chip comprising a first junction field-effect transistor within a termination ring. A second junction field-effect transistor within the termination ring. An isolation region within the termination ring, wherein the isolation region separates the first junction field-effect transistor from the second junction field-effect transistor.

### CROSS-REFERENCE TO RELATED APPLICATION

The present application claims priority to U.S. Provisional Patent Application No. 63/684,946 filed on Aug. 20, 2024, the contents of which are hereby incorporated by reference in their entirety.

### TECHNICAL FIELD

The present disclosure relates generally to semiconductor chips, and more specifically to Junction Field Effect Transistors and methods for manufacturing same to improve the performance of the transistor.

### SUMMARY

According to an aspect of one or more examples, there is provided a semiconductor chip comprising a termination ring, a first junction field effect transistor within said termination ring, a second junction field effect transistor within said termination ring, and an isolation region within said termination ring, wherein the isolation region separates the first junction field effect transistor from the second junction field effect transistor. The isolation region may comprise oxide, nitride or a combination of oxide and nitride. The termination ring may comprise an edge termination region. The edge termination region may comprise a mesa structure, guard rings, field plates, high resistivity region by ion implantation, or a combination thereof.

According to an aspect of one or more examples, there is provided a semiconductor chip comprising a termination ring, a first junction field effect transistor within said termination ring, a second junction field effect transistor within said termination ring, an isolation region within said termination ring, wherein the isolation region separates the first junction field effect transistor from the second junction field effect transistor, a source of the first junction field-effect transistor connected to a source of the second junction field-effect transistor, and a first gate of the first junction field-effect transistor connected to a first gate of the second junction field-effect transistor. The semiconductor chip may comprise a second gate of the first junction field-effect transistor connected to a second gate of the second junction field-effect transistor. The isolation region may comprise oxide, nitride or a combination of oxide and nitride. The termination ring may comprise an edge termination region. The edge termination region may comprise a mesa structure, guard rings, field plates, high resistivity region by ion implantation, or a combination thereof.

According to an aspect of one or more examples, there is provided a method of manufacturing a semiconductor chip, the method may comprise forming a termination ring, forming a first junction field effect transistor within said termination ring, forming a second junction field effect transistor within said termination ring, and forming an isolation region within said termination ring, wherein the isolation region separates the first junction field effect transistor from the second junction field effect transistor. The method of manufacturing the semiconductor chip may comprise a source of the first junction field effect transistor that may be connected to a source of the second junction field effect transistor. The method of manufacturing the semiconductor chip may comprise a first gate of the first junction field effect transistor that may be connected to a first gate of the second junction field effect transistor. The method of manufacturing the semiconductor chip may comprise a second gate of the first junction field effect transistor that may be connected to a second gate of the second junction field effect transistor. The isolation region may comprise oxide, nitride or a combination of oxide and nitride. The termination ring may comprise an edge termination region. The edge termination region may comprise a mesa structure, guard rings, field plates, high resistivity region by ion implantation, or a combination thereof.

### BRIEF DESCRIPTION OF DRAWINGS

FIG. 1 is a cross sectional view of a semiconductor chip according to one or more examples.

FIG. 2 is a cross sectional view of a semiconductor chip according to one or more examples.

### DETAILED DESCRIPTION OF VARIOUS EXAMPLES

Reference will now be made in detail to the following various examples, which are illustrated in the accompanying drawings, wherein like reference numerals refer to like elements throughout. The following examples may be in various forms without being limited to the examples set forth herein.

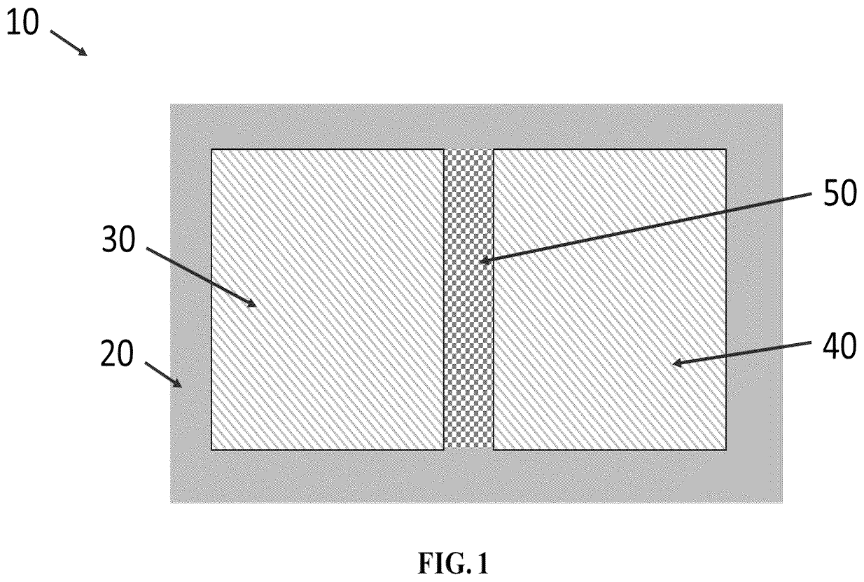

FIG. 1 shows a cross sectional view of a semiconductor chip 10 according to one or more examples. The example semiconductor chip of FIG. 1 may include a termination ring 20 that defines the semiconductor chip 10 area. The termination ring 20 may comprise an edge termination region. The edge termination region may comprise a mesa structure, guard rings, field plates, high resistivity region by ion implantation, or a combination thereof. The example semiconductor chip 10 of FIG. 1 may also include a first junction field effect transistor 30 and a second junction field effect transistor 40 that may be separated by an isolation region 50 within the termination ring 20. The isolation region 50 separates the first junction field effect transistor 30 from the second junction field effect transistor 40. The isolation region 50 may comprise oxide, nitride or a combination of oxide and nitride.

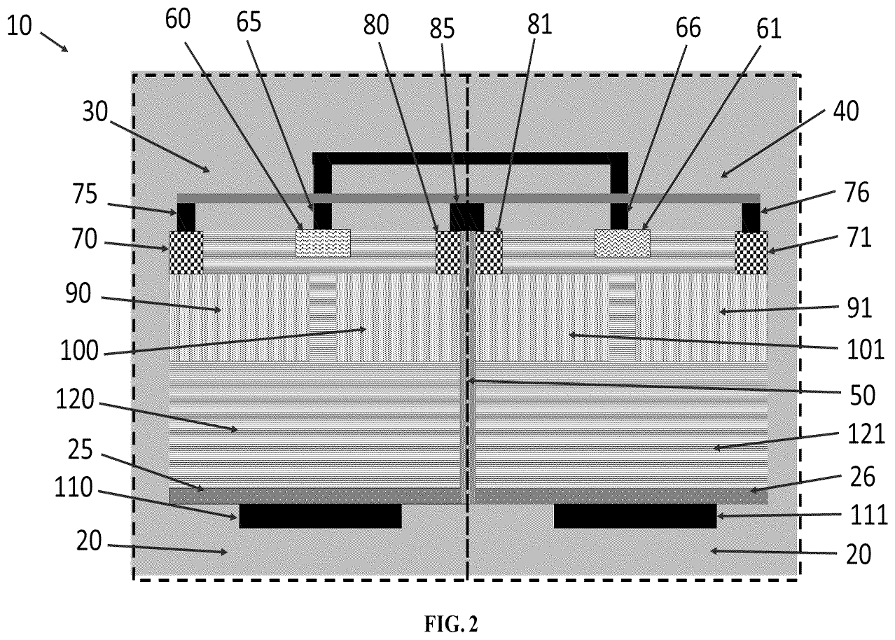

FIG. 2 shows a cross sectional view of a semiconductor chip 10 according to one or more examples. The example semiconductor chip 10 of FIG. 2 may include a termination ring 20 that defines the semiconductor chip 10 area. The termination ring 20 may comprise an edge termination region. The edge termination region may comprise a mesa structure, guard rings, field plates, high resistivity region by ion implantation, or a combination thereof. The example semiconductor chip 10 of FIG. 2 may also include a first junction field effect transistor 30 and a second junction field effect transistor 40 that may be separated by an isolation region 50 within the termination ring 20. The isolation region 50 separates the first junction field effect transistor 30 from the second junction field effect transistor 40. The isolation region 50 may comprise oxide, nitride or a combination of oxide and nitride. The first junction field effect transistor 30 of the example semiconductor chip 10 of FIG. 2 may include a substrate 25. The second junction field effect transistor 40 of the example semiconductor chip 10 of FIG. 2 may include a substrate 26. The substrate 25 of the first junction field effect transistor 30 and the substrate 26 of the second junction field effect transistor 40 shown in FIG. 2 may have a first concentration of a first type dopant. The first junction field effect transistor 30 of the example semiconductor chip 10 of FIG. 2 may include a drain contact 110 that may be formed at a first side of the substrate 25 of the first junction field effect transistor 30. The second junction field effect transistor 40 of the example semiconductor chip 10 of FIG. 2 may include a drain contact 111 that may be formed at a first side of the substrate 26 of the second junction field effect transistor 40. The first junction field effect transistor 30 of the example semiconductor chip 10 of FIG. 2 may include a drift layer 120 formed within the substrate 25 at a second side of the substrate 25 of the first junction field effect transistor 30. The second junction field effect transistor 40 of the example semiconductor chip 10 of FIG. 2 may include a drift layer 121 formed within the substrate 26 at a second side of the substrate 26 of the second junction field effect transistor 40. The second side of the substrate 25, 26 is opposite the first side of the substrate 25, 26 where the respective drain contact 110, 111 was formed for the first junction field effect transistor 30 and the second junction field effect transistor 40. The drift layer 120 of first junction field effect transistor 30 and the drift layer 121 the second junction field effect transistor 40 may comprise a second concentration of the first type dopant, wherein the first concentration of first type dopant in the respective portion of the substrate 25 of the first junction field effect transistor 30 and the respective portion of the substrate 26 of the second junction field effect transistor 40 may be greater than the second concentration of first type dopant in the respective portion of the drift layer 120 of the first junction field effect transistor 30 and the respective portion of the drift layer 121 of the second junction field effect transistor 40. The first junction field effect transistor 30 of the example semiconductor chip 10 of FIG. 2 may include a plurality of well implant layers 90, 100 formed into the drift layer 120 of the first junction field effect transistor 30. The second junction field effect transistor 40 of the example semiconductor chip 10 of FIG. 2 may include a plurality of well implant layers 91, 101 formed into the drift layer 121 of the second junction field effect transistor 40. The plurality of well implant layers 90, 100 of the first junction field effect transistor 30 and the plurality of well implant layers 91, 101 of the second junction field effect transistor 40 may comprise a third concentration of a second type dopant that may have a peak doping in the range 1E17 to 5E18. The first junction field effect transistor 30 of the example semiconductor chip 10 of FIG. 2 may include a source implant layer 60 formed into the drift layer 120 of the first junction field effect transistor 30. The second junction field effect transistor 40 of the example semiconductor chip 10 of FIG. 2 may include a source implant layer 61 formed into the drift layer 121 of the second junction field effect transistor 40. The source implant layer 60 of the first junction field effect transistor and the source implant layer 61 of the second junction field effect transistor 40 may comprise a fourth concentration of the first type dopant. The first junction field effect transistor 30 of the example semiconductor chip 10 of FIG. 2 may include a source contact 65 operatively connected to the source layer 60 of the first junction field effect transistor 30. The second junction field effect transistor 40 of the example semiconductor chip 10 of FIG. 2 may include a source contact 66 operatively connected to the source layer 61 of the second junction field effect transistor 40. The source contacts may be made from a metal, polysilicon, or other suitable material. The source contact 65 of the first junction field effect transistor 30 may be connected to the source contact 66 of the second junction field effect transistor 40. The first junction field effect transistor 30 of the example semiconductor chip 10 of FIG. 2 may include a first gate implant layer 70 and a second gate implant layer 80 formed into the respective portion of the drift layer 120 of the first junction field effect transistor 30. The second junction field effect transistor 40 of the example semiconductor chip 10 of FIG. 2 may include a first gate implant layer 71 and a second gate implant layer 81 formed into the respective portion of the drift layer 121 of the second junction field effect transistor 40. The first gate implant layer 70 and the second gate implant layer 80 of the first junction field effect transistor 30 and the first gate implant layer 71 and the second gate implant layer 81 of the second junction field effect transistor 40 may comprise a fifth concentration of the second type dopant. The first junction field effect transistor 30 of the example semiconductor chip 10 of FIG. 2 may include a first gate contact 75 operatively connected to the first gate implant layer 70 and a second gate contact 85 operatively connected to the second gate implant layer 80. The second junction field effect transistor 40 of the example semiconductor chip 10 of FIG. 2 may include a second gate contact 76 operatively connected to the second gate implant layer 71 and a second gate contact 85 operatively connected to the second gate implant layer 81. The first gate contacts and the second gate contact may be made from a metal, polysilicon, or other suitable material. The first gate contact 75 of the first junction field effect transistor 30 may be connected to the first gate contact 76 of the second junction field effect transistor 40. The first junction field effect transistor 30 and the second junction field effect transistor 40 of the example semiconductor chip 10 of FIG. 2 may also share the second gate contact 85 that is operatively connected to the respective second gate 80, 81 of the first junction field effect transistor 30 the second junction field effect transistor 40.

In one example, the first junction field effect transistor 30 and the second junction field effect transistor 40 of the example semiconductor chip 10 of FIG. 2, may have the first type dopant be an n-type dopant and the second type dopant be a p-type dopant. In another example, the first junction field effect transistor 30 and the second junction field effect transistor 40 of the example semiconductor chip 10 of FIG. 2, may have the first type dopant be a p-type dopant and the second type dopant be an n-type dopant.

Various examples have been disclosed herein, in connection with the above description and the drawings. It will be understood that it would be unduly repetitious to literally describe and illustrate every combination and subcombination of these examples. Accordingly, all examples may be combined in any way and/or combination, and the present specification, including the drawings, shall be construed to constitute a complete written description of all combinations and subcombinations of the examples described herein, and of the manner and process of making and using them, and shall support claims to any such combination or subcombination.

It will be appreciated by persons skilled in the art that the examples described herein are not limited to what has been particularly shown and described herein above. In addition, unless mention was made above to the contrary, it should be noted that all of the accompanying drawings are not to scale. A variety of modifications and variations are possible in light of the above teachings.

What is claimed is:

1. A semiconductor chip comprising:
a termination ring;
a first junction field-effect transistor within said termination ring;
a second junction field-effect transistor within said termination ring; and
an isolation region within said termination ring, wherein the isolation region separates the first junction field-effect transistor from the second junction field-effect transistor.

2. The semiconductor chip of claim 1, wherein the isolation region comprises oxide, nitride or a combination of oxide and nitride.

3. The semiconductor chip of claim 1, wherein the termination ring comprises an edge termination region.

4. The semiconductor chip of claim 3, wherein the edge termination region comprises a mesa structure, guard rings, field plates, high resistivity region by ion implantation, or a combination thereof.

5. A semiconductor chip comprising:
a termination ring;
a first junction field-effect transistor within said termination ring;
a second junction field-effect transistor within said termination ring;
an isolation region within said termination ring, wherein the isolation region separates the first junction field-effect transistor from the second junction field-effect transistor;
a source of the first junction field-effect transistor connected to a source of the second junction field-effect transistor; and
a first gate of the first junction field-effect transistor connected to a first gate of the second junction field-effect transistor.

6. The semiconductor chip of claim 5, wherein a second gate of the first junction field-effect transistor connected to a second gate of the second junction field-effect transistor.

7. The semiconductor chip of claim 5, wherein the isolation region comprises oxide, nitride or a combination of oxide and nitride.

8. The semiconductor chip of claim 5, wherein the termination ring comprises an edge termination region.

9. The semiconductor chip of claim 8, wherein the edge termination region comprises a mesa structure, guard rings, field plates, high resistivity region by ion implantation, or a combination thereof.

10. A method of manufacturing a semiconductor chip, the method comprising:
forming a termination ring;
forming a first junction field-effect transistor within said termination ring;
forming a second junction field-effect transistor within said termination ring; and
forming an isolation region within said termination ring, wherein the isolation region separates the first junction field-effect transistor from the second junction field-effect transistor.

11. The method of claim 10, wherein a source of the first junction field-effect transistor connected to a source of the second junction field-effect transistor.

12. The method of claim 11, wherein a first gate of the first junction field-effect transistor connected to a first gate of the second junction field-effect transistor.

13. The method of claim 12, wherein a second gate of the first junction field-effect transistor connected to a second gate of the second junction field-effect transistor.

14. The method of claim 10, wherein a first gate of the first junction field-effect transistor connected to a first gate of the second junction field-effect transistor.

15. The method of claim 14, wherein a second gate of the first junction field-effect transistor connected to a second gate of the second junction field-effect transistor.

16. The semiconductor device of claim 10, wherein the isolation region comprises oxide, nitride or a combination of oxide and nitride.

17. The method of claim 10, wherein the termination ring comprises an edge termination region.

18. The method of claim 17, wherein the edge termination region comprises a mesa structure, guard rings, field plates, high resistivity region by ion implantation, or a combination thereof.
